(19) United States
(12) Patent Application Publication
(10) Pub. No.: US 2008/0128109 A1
(43) Pub. Date: Jun. 5, 2008

(54) Two-phase cooling technology for electronic cooling applications

(76) Inventors: Paul J. Gwin, Orangevale, CA (US); Mark A. Trautman, Aloha, OR (US)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/170,846

(22) Filed: Jun. 29, 2005

(51) Int. Cl. H05K 7/20; F28D 15/00

(52) U.S. Cl. 165/80.3; 165/104.21; 165/104.33; 361/700

(57) ABSTRACT

A device to efficiently boil and distribute liquid vapor by using a high efficiency heat exchanger technology that incorporates the high heat spreading capability of two-phase heat transfer physics. The evaporation/boiling permits the heat load from a discrete component to be efficiently spread via vapor transport to the entire HEX fin array. In doing so, both the spreading resistance and air-side convective resistance may be made superior to air-cooled technologies alone and rival liquid cooling performance, but without moving parts or need of a mechanical pump. One embodiment is the combination of highly effective vapor distribution and liquid condensate return channels, a high surface area air-side heat exchanger that serves as the vapor condenser, and an efficient evaporation chamber to form a complete thermal solution.

### BACKGROUND INFORMATION

Microelectronic devices generate heat as a result of the electrical activity of the internal circuitry. In order to minimize the damaging effects of this heat, thermal management systems have been developed to remove the heat. Such thermal management systems have included heat sinks, heat spreaders, and fans, and various combinations that are adapted to thermally couple with the microelectronic device. With the development of faster, more powerful, and more densely packed microelectronic devices such as processors, improved cooling technology is needed to remove the generated heat to prevent overheating.

FIG. 1 illustrates a prior art two-phase heat transfer device 100. In current two-phase heat transfer devices, the heat comes from a processor into a copper block (not shown). The copper block transfers the heat into round tubes or heat pipes 105. The heat, in liquid form, is transferred into vapor by an evaporator (not shown). The vapor travels through the round tube 105 where the heat is transferred to air-side-fins 110 attached to the tube 105. As the heat pipes 105 run through the fins, it releases its heat to the fins 110. Air is blown through the fins 110 causing heat to be removed from a heat sink (not shown). However, the heat pipes 105 have a small contact area with the fins 110 that imposes an undesirable thermal resistance and the heat must conduct a relatively long way from the tube 105 to the end of the fin 110 resulting in severe fin efficiency losses.

In current designs, the transfer of heat from the vapor to the air-side-fins 110 is extremely inefficient because of a limited contact area between the pipe 105 circumference and the surrounding fin material. Furthermore, it is well known that the fin efficiency decreases with fin length, and in this tube-fin design the fin length (as measured from the tube) is quite long, resulting in poor heat transfer from the fins to the air. Thus, the lack of vapor distribution of current heat pipe heat sinks make them inherently less efficient than theoretically possible due to a small condenser-to-fin contact area and low fin efficiency. Therefore a need exists for a larger condenser to fin contact area and greater fin efficiency.

### BRIEF DESCRIPTION OF THE DRAWINGS

Various features of the invention will be apparent from the following description of preferred embodiments as illustrated in the accompanying drawings, in which like reference numerals generally refer to the same parts throughout the drawings. The drawings are not necessarily to scale, the emphasis instead being placed upon illustrating the principles of the inventions.

FIG. 1 is a prior art figure of a two-phase heat transfer device.

FIG. 2a is a cross section view of one embodiment of a heat exchanger.

FIG. 2b is a front side view of the heat exchanger of FIG. 2a.

FIG. 3a is a cross-section view of second embodiment of a heat exchanger.

FIG. 3b is a front side view of the heat exchanger of FIG. 3a.

FIG. 4 is a graph illustrating evaporator power dissipation capability.

FIG. 5 is a flowchart of an example microelectronic cooling method, according to one example embodiment.

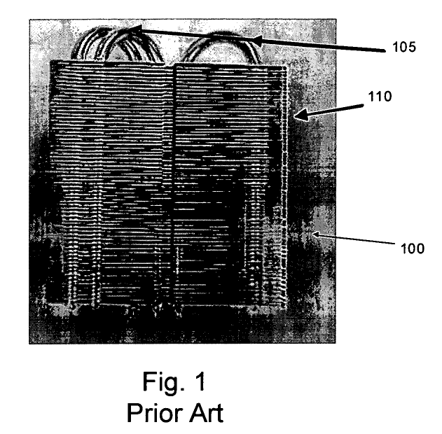

### DETAILED DESCRIPTION

In the following description, for purposes of explanation and not limitation, specific details are set forth such as particular structures, architectures, interfaces, techniques, etc. in order to provide a thorough understanding of the various aspects of the invention. However, it will be apparent to those skilled in the art having the benefit of the present disclosure that the various aspects of the invention may be practiced in other examples that depart from these specific details. In certain instances, descriptions of well-known devices, circuits, and methods are omitted so as not to obscure the description of the present invention with unnecessary detail.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

Microchannel heat exchangers and associated techniques are emerging as an improved thermal solution for high-power, densely populated microelectronic devices such as processors and other integrated circuit (IC) dies. One such technique employs a microchannel heat exchanger in a dual-phase, liquid-vapor cooling system, wherein the coolant undergoes vaporization during the heat transfer process.

In the preferred embodiments, this device efficiently boils and distributes liquid vapor by using a high efficiency heat exchanger technology that incorporates the high heat spreading capability of two-phase heat transfer physics. The evaporation/boiling permits the heat load from a discrete component to be efficiently spread via vapor transport to the entire HEX fin array. In doing so, both the spreading resistance and air-side convective resistance may be made superior to air-cooled technologies alone and rival liquid cooling performance, but without moving parts or need of a mechanical pump. One embodiment is the combination of highly effective vapor distribution and liquid condensate return channels, a high surface area air-side heat exchanger that serves as the vapor condenser, and an efficient evaporation chamber to form a complete thermal solution.

In addition, the HEX fin array solves the vapor distribution and contact area issue that thermally handicap the current heat-pipe and thermo-siphon technologies by using a very efficient vapor-to-fin heat exchanger design combined with a high efficiency and compact airside fin structure. Furthermore, the technology maximizes the wetted surface area of the condenser which minimizes the thermal contact resistance between the condenser and the fins as well as the inherent condensation resistance. Because the vapor is transported uniformly through the condenser surfaces it also allows the use of short fin structures that are thermally efficient.

Beyond these significant thermal advantages, the technology may be designed to operate in multiple orthogonal orientations relative to the gravitational force that returns the condensate and can be designed to work with a partial wick structure or grooved tube geometry to allow all operating orientations. To accomplish this, the evaporator on the thermo-siphon configuration is offset to allow for at least two orientations that allow gravity to return the fluid to the evaporator. The evaporator condenser tubes can also be slightly bowed or angled to force the condensed fluid to exit the vapor tubes and return to the evaporator.

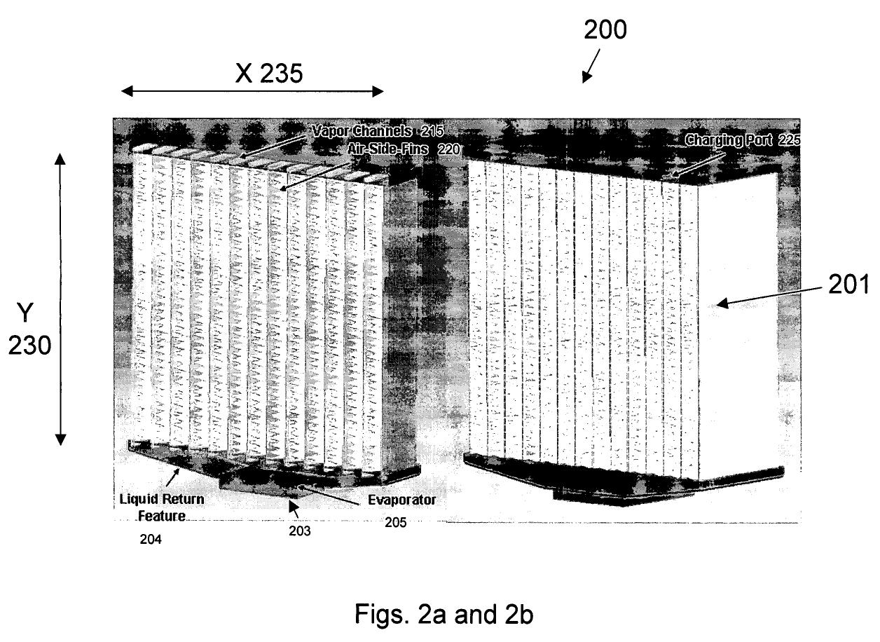

FIGS. 2a and 2b illustrate one embodiment of a finned heat exchanger 200. As shown in FIGS. 2a and 2b, the finned heat exchanger 200 includes a fin array 201. The fin array 201 includes a plurality of air side fin members 220. Further, each fin member 220 is arranged in a row, horizontally; and hollow vertical channels 215 connect to each fin 220 at both ends of the fin 220. This enables the fins 220 to be very short in a horizontal dimension. The shorter fin may enable the device to have better heat transfer efficiency. Specifically, each fin 220 has generally square or rectangular cross-section. Furthermore, the fins 220 are arranged in a row along the channels 215 at regularly spaced intervals.

According to an embodiment of the invention, the channels 215 are located at each end of the fins 220 to create the fin array 201. The channels 215 are elongated, hollow tubes. The spacing of these flat vapor tubes 215 is design selectable. Each channel 215 extends to the length of the fin array 201. In some embodiments, the channels 215 may contain grooves as liquid return paths which maximizes the fluid return rate and minimizes return of fluid due to counter-flowing vapor flow over the liquid. In addition, this fin array 201 with the channels 215 creates a heat exchanger with significantly larger condenser to fin contact area, thus creating greater fin efficiency.

The fin array is mounted on top of a copper block 203. The bottom of the copper block 203 is attached to a processor (not shown). The choice of material for the block or base 203 may vary by application. The copper block 203 may be in intimate contact with boiling fluid located in a fluid pooling zone 204. A fluid pooling zone 204 is filled with liquid and the heat from the processor may boil the liquid off into an evaporator 205.

The enhanced surface effectively creates nucleation sites. By nucleation sites, we mean a pool of liquid so the device does not run out of liquid to cool the surface at the same power level. This ensures an inexhaustible supply of fluid around these nucleation sites since the fluid is always being replenished.

The heat introduced at the evaporator 205 boils the liquid into vapor similar to a conventional heat-pipe or thermo-siphon. The vapor is then distributed to the HEX condenser through an array 201 of vapor spreading channels 215. There is a pressure difference that drives the vapor from the evaporator 205 to the channels 215. The vapor flows into all the channels 215 and provides a fairly uniform heat in the hollow tube design. The channels 215 then releases heat out to the fins 220.

The vapor condenses on the channel walls and transfers its heat load to airside fins 220 where the heat is rejected to the embedding air stream. The condensate created in this process returns to the evaporator 205 by gravity (for thermo-siphon) or via capillary forces (if a wick structure is incorporated). The large heat spreading capability that this technology allows the heat to be spread uniformly to the efficient airside HEX fins 220 and thus results in a lower airside thermal resistance than other known passive cooling technologies.

FIG. 2b illustrates a front side view of the heat exchanger. In order for the heat exchanger to operate, fluid is necessary. In one embodiment, the process may include at least one charging port 225. In operation, to charge this device, first attach a valve system and attach the port 225 to the device. Evacuate all the air or gas outside of that device. Thereby removing all the gas. Once all the gas is removed, and then another valve is opened up which would allow the boiled fluid to get sucked in there. The device does not have to be completely filled; it would depend on the implementation.

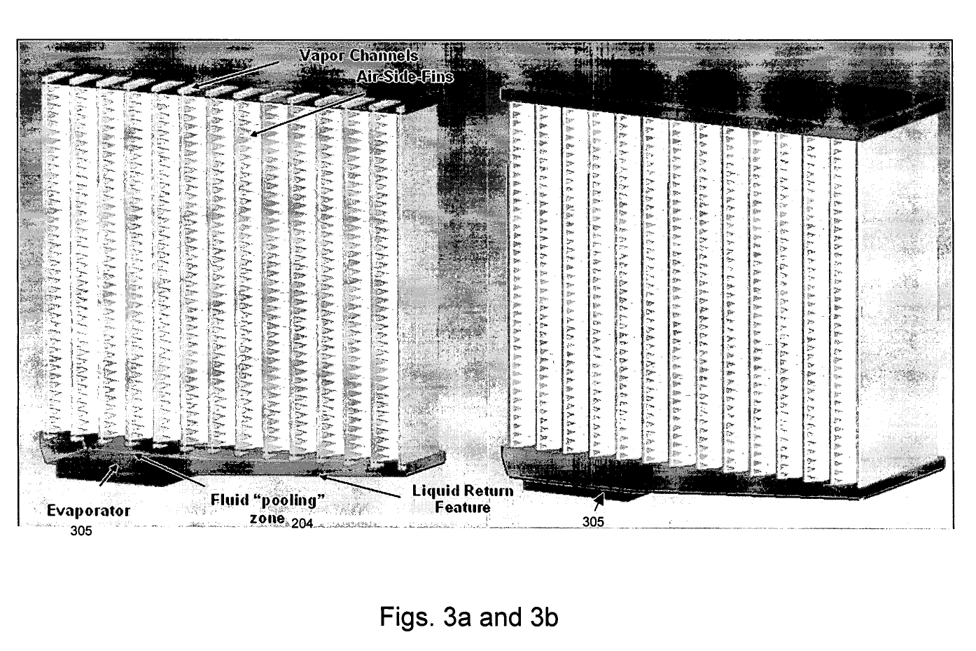

FIGS. 3a and 3b illustrate another embodiment of the heat exchanger. When the vapor condenses inside the vapor channels 215, it needs to return back into the evaporator 205 or liquid pooling zone 204. The liquid may return to the evaporator surface due to gravity. Since this may occur, a designer may limit the orientation in which the heat exchanger 200 would reside with in a microelectronic device.

For example, in a standard pc, the heat exchanger 200 may be positioned such that gravity is pulling the liquid down as shown in the orientation of FIGS. 2 and 3. This situation is ideal because gravity will pull liquid back to the evaporator 205. But if the heat exchanger or pc was rotated 90 degrees, the evaporator 205, as positioned in FIG. 2, will not fully cover the evaporator surface. The amount of coverage will always depend on the amount of liquid on the evaporator surface. One way to resolve this is to offset the evaporator 305 from the center. Then if the device or pc is rotated, liquid will still cover the evaporator surface.

In another embodiment, when the vapor is traveling through the channels 215, the vapor condenses on the wall of the channels and the liquid may flow down on the wall due to gravity. The vapor going up through the channels 215 may pull liquid up with it. However, if grooves (not shown) are placed within the channels, this may create additional room for the vapor to flow and protect the liquid by having the groove interface.

In FIGS. 2 and 3, the length X 235 and width Y 230 of the heat exchanger 200 may be designed to accommodate different sizes. During design, length X 235 and width Y 230 may be adjusted by varying the dimensions of the heat exchanger's 200 subcomponents in each direction. Those skilled in the art will appreciate that the dimensions may be designed to improve heat transfer in accordance with coolant properties. Though the heat exchanger 200 depicted in this embodiment is square, the shape will generally correspond to the die to which the heat exchanger is thermally coupled and is adaptable. Likewise the vapor channels 215 may vary in shape such that the channels may be rounded as opposed to rectangular or may embody other geometries to accommodate heat transfer characteristics such as temperature and pressure drop profiles.

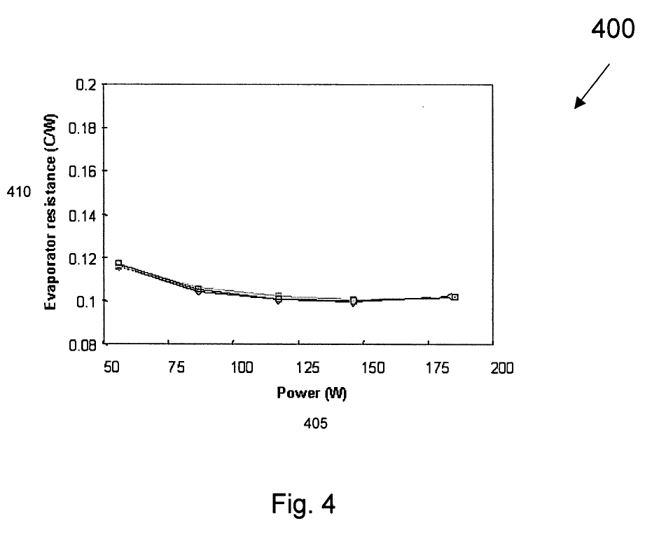

FIG. 4 illustrates a graph 400 of one example of the thermo performance and power dissipation ability of the device of FIGS. 2 and 3. Based on the graph, the device allows greater than 200 W power 405 dissipation. The graph indicates that dissipation is possible without dry-out, when compared to 100 W typical limit for traditional heat pipe designs. Thus indicating sufficient amount of working fluid. In addition, the analysis shows that approximately 0.08 C/W 410 reductions from reduced spreading, evaporation, contact, and condenser resistance.

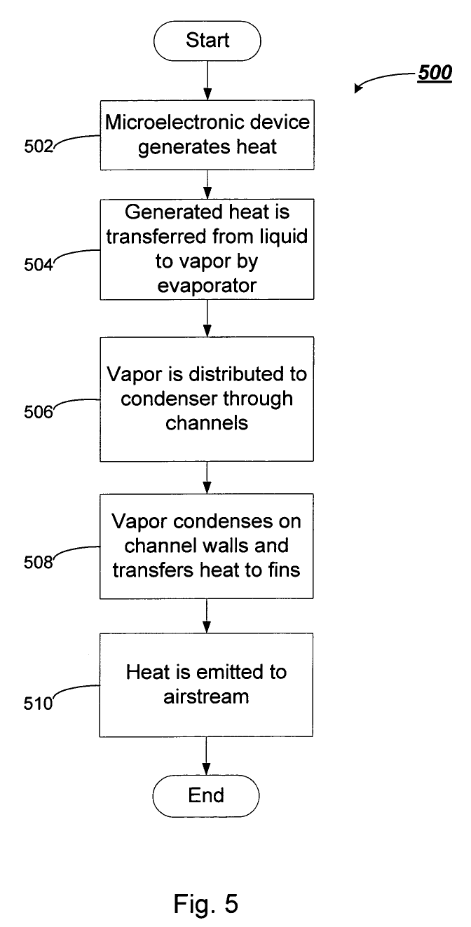

FIG. 5 provides a flow chart of an example microelectronic cooling method, according to but one example embodiment. In accordance with this flow chart 500, a microelectronic device 200, when actuated, generates heat, block 502 and the heat is transformed from liquid to vapor by an evaporator 205, block 504. The vapor is distributed to the fin array 201 through the channels 215, block 506. The vapor condenses on the channel walls and transfers heat to the fins 220, block 508. The absorbed heat may be emitted to the air stream, block 510.

It should be noted that the process or processes of FIG. 5 may be continuous. The method may be part of a closed-loop or open-loop process. These steps may occur out of sequence or not at all.

Advantageously, this high efficiency heat exchanger in combination with the evaporator forms a scalable heat sink architecture that may be used in BTX, server and future digital home platforms of Intel. The advantage of a low thermal resistance and high efficiency fin array means that it may be employed as a low acoustic noise solution. The solution is essentially an efficient heat spreader that is much more effective than copper and much lighter in weight. As discussed earlier, significant weight reduction is possible over existing thermal solutions and this can reduce platform cost (chassis+shipping+engineering) that would normally be needed to ensure the survivability of high mass platforms during shipping. Furthermore, the high power dissipation capability of such a solution (>200 W) means that it could be used as a common thermal solution for Intel's multiple-processor or multi-chip platforms by including multiple evaporators that link to a common exchanger. Finally, the design lends itself to scalable performance. Higher power platforms could make use of relatively larger heat exchanger, but the basic concept would scale over a wide range of platforms.

In summary, this invention protects Intel's ability to develop advanced thermal solutions that have the potential to deliver best of class thermal performance for Intel platforms and postpone or eliminate the need for more expensive cooling technologies such as liquid cooling or refrigeration.

What is claimed is:

1. A method comprising:
generating heat in a microelectronic device;
transferring heat to a fin array; and
emitting heat from fin array.

2. The method of claim 1 further comprising transforming generated heat from liquid to vapor.

3. The method of claim 2 further comprising distributing the vapor through channels.

4. The method of claim 3 wherein distributing the vapor condenses on channel walls.

5. The method of claim 4, wherein the condensing of vapor transfers heat to fin array.

6. A fin array, comprising:
a plurality of fin members, each fin member arranged in a row; and
at least one channel for connecting the plurality of fin members, each channel arranged vertically,
wherein each fin member is arranged in a row at predetermined spacing and each channel is arranged vertically at predetermined spacing extending to the length of the fin array.

7. The fin array of claim 6 wherein the channels are elongated and hollow.

8. The fin array of claim 7, wherein the both ends of each fin member attaches to a channel.

9. The fin array of claim 8, wherein each fin member is short.

10. The fin array of claim 6, wherein the channel may include grooves.

11. A heat exchanger comprising:
a thermally conductive base;
an evaporator coupled to the thermally conductive base, wherein the evaporator includes a fluid area;
a fin array having a least one channel and a plurality of fin members;
wherein vapor flows into the channels to provide uniform heat distribution in a condenser.

12. The heat exchanger of claim 11 wherein the thermally conductive base is a copper base.

13. The heat exchanger of claim 11, wherein the thermally conductive base is in contact with a microelectronic device.

14. The heat exchanger of claim 11 wherein the thermally conductive base is in contact with the fluid area.

15. The heat exchanger of claim 14, wherein the fluid area is filled with liquid.

16. The heat exchanger of claim 11, wherein the evaporator contains an enhanced surface creating nucleation sites.

17. The heat exchange of claim 16, wherein the nucleation sites contain an inexhaustible supply of fluid.

18. The heat exchanger of claim 14, wherein the evaporator transforms the liquid in the fluid area into vapor.

19. The heat exchanger of claim 18, wherein the channels are hollow.

20. The heat exchanger of claim 19, wherein the vapor is driven from the evaporator to the channels by a pressure difference.

21. The heat exchanger of claim 19, wherein the vapor flows through all the channels to create a uniform heat throughout the condenser.

22. The heat exchanger of claim 20, the channels release heat out to the fin members.

23. The heat exchanger of claim 22, wherein the vapor condenses on the channels walls to transfer heat to the fin members.

24. The heat exchanger of claim 23, wherein the fin members release the heat into the air.

25. The heat exchanger of claim 11 further comprising a charging port.

26. The heat exchanger of claim 11 wherein the evaporator is offset from the center.

27. The heat exchanger of claim 11, wherein the channels contain grooves.

28. The heat exchanger of claim 11, wherein the size of the fin array may vary.

29. The heat exchanger of claim 11, wherein the fin members are of varying shapes.
